(19) United States
(12) Patent Application Publication
(10) Pub. No.: US 2008/0298023 A1
(43) Pub. Date: Dec. 4, 2008

(54) ELECTRONIC COMPONENT-CONTAINING MODULE AND MANUFACTURING METHOD THEREOF

(75) Inventors: Rikiya Okimoto, Osaka (JP); Tsukasa Shiraishi, Osaka (JP); Yukihiro Ishimaru, Osaka (JP); Toshiyuki Kojima, Osaka (JP)

Correspondence Address: RATNERPRESTIA, P.O. BOX 980, VALLEY FORGE, PA, 19482, US

(73) Assignee: Matsushita Electric Industrial Co., Ltd., Osaka (JP)

(21) Appl. No.: 12/127,123

(22) Filed: May 27, 2008

(30) Foreign Application Priority Data
May 28, 2007 (JP) 2007-141062

(51) Int. Cl. H05K 7/20; H05K 3/30

(52) U.S. Cl. 361/715; 29/836

(57) ABSTRACT

An electronic component-containing module includes an electrically insulating substrate; and a first electronic component and second electronic component embedded in the electrically insulating substrate, wherein the first electronic component protrudes partially from at least one surface of the electrically insulating substrate, and the second electronic component is contained in the electrically insulating substrate.

### BACKGROUND OF THE INVENTION

1. Field of the Invention

The present invention relates to an electronic component-containing module in which passive components such as resistors and capacitors or active components such as semiconductor devices are contained in an electrically insulating substrate as well as to a manufacturing method for the electronic component-containing module.

2. Related Art of the Invention

Recently, along with size and weight reduction of electronic equipment, there has been growing demand for greater packaging density of printed wiring boards and downsizing of mounted components. In the printed wiring board, the packaging density has been increased in a direction parallel to a surface of the wiring board due to smaller dimensions required by wiring rules. Furthermore, the packaging density can be increased even in a direction perpendicular to the surface of the wiring board if wiring is stacked using a build-up process and an inner via is formed between desired layers.

For high-density mounting, 1005-size or even smaller 0603-size chip components are used. Regarding semiconductor packages, SOP (Small Outline Package), QFP (Quad Flat Package), and other surface-mounted devices which have high-pin-count leads around the package are often used conventionally. Recently, to further downsize semiconductor packages, chip size packaging (CSP) is used by the application of flip-chip interconnection with an active device layer of an IC chip turned to the printed wiring board. With flip-chip interconnection, bare ICs are mounted directly on a printed wiring board via solder bumps or Au stud bumps without using leads.

In the case of the flip-chip mounting, an area on which the IC chips can be mounted is a surface of the printed wiring board and mounting density is limited by substrate size. Thus, it is difficult to further increase the mounting density dramatically. On the other hand, three-dimensional mounting techniques have been developed which involve building thin-film components, or incorporating existing chip components such as semiconductor devices and LCRs, into a substrate for realizing high-density mounting (see for example Japanese Patent Laid-Open No. 11-220262 and Japanese Patent Laid-Open No. 2002-57276).

Examples include an electronic component-containing module in which existing active or passive components are embedded in a substrate which uses a mixture of an inorganic filler and thermosetting resin as a composite material.

The electronic component-containing module, which uses the mixture of the inorganic filler and thermosetting resin as a substrate material, consequently has a low dielectric constant and high heat dissipation capabilities and allows existing components to be embedded in a substrate easily.

This makes it possible to form wiring patterns with short wires and easy to provide shielding effects, and thereby makes it possible to implement a high-density, three-dimensional circuit module capable of high-frequency operation and superior in noise immunity. In order to establish vertical conducting connections in the substrate made of the composite material, internal wiring is formed by producing inner vias in the substrate and filling them with a conductive resin paste.

A manufacturing method for a conventional electronic component-containing module will be described below with reference to drawings.

FIGS. 17(A) to 17(D) are sectional views showing manufacturing processes of the conventional electronic component-containing module.

First, as shown in FIG. 17(A), electronic components 1402 and 1403 are mounted on a die release carrier 1407a on which a wiring pattern 1405a has been formed. The electronic components 1402 and 1403 differ in thickness from each other. For example, the electronic component 1402 is a component package such as QFP or CSP and the electronic component 1403 is a chip resistor or bare chip.

Next, as shown in FIG. 17(B), the electrically insulating substrate 1404 having an inner via 106 is aligned with and stacked on the die release carrier 1407a on which the wiring pattern 1405a has been formed and the electronic components 1402 and 1403 have been mounted, with an inner via 1406 being aligned with the wiring pattern 1405a.

Furthermore, a die release carrier 1407b on which a wiring pattern 1405b has been formed is aligned with and stacked on the electrically insulating substrate 1404.

Next, as shown in FIG. 17(C), pressure and heat are applied simultaneously from outside the die release carriers 1407a and 1407b.

Finally, as shown in FIG. 17(D), the die release carriers 1407a and 1407b are removed to complete the electronic component-containing module 1401.

However, the conventional electronic component-containing module described above has the following problem. Namely, since the electrically insulating substrate 1404 contains all the electronic components 1402 and 1403 of different thicknesses, thickness of the electrically insulating substrate 1404 is set to height of the thickest electronic component 1402. This increases the overall thickness of the electronic component-containing module.

The present invention has been made in view of the above problem and has an object to provide an electronic component-containing module which can reduce thickness of an electrically insulating substrate and thereby reduce overall size.

### SUMMARY OF THE INVENTION

The 1^{st} aspect of the present invention is an electronic component-containing module, comprising:

an electrically insulating substrate; and

a plurality of electronic components embedded in the electrically insulating substrate,

wherein at least one of the plurality of electronic components is a protruding electronic component, part of which protrudes above at least one surface of the electrically insulating substrate, and

the electronic components other than the protruding electronic component are contained so that they do not extend past said at least one surface of the electrically insulating substrate.

The 2^{nd} aspect of the present invention is the electronic component-containing module according to the 1^{st} aspect of the present invention, further comprising an electrode installed at least on the surface of the electrically insulating substrate, from which the protruding electronic component is exposed, wherein

the protruding electronic component is electrically connected at least to the electrode outside the electrically insulating substrate.

The 3^{rd} aspect of the present invention is the electronic component-containing module according to the 1^{st} aspect of the present invention, wherein the protruding electronic component is located above the other electronic components.

The 4^{th} aspect of the present invention is the electronic component-containing module according to the 1^{st} aspect of the present invention, further comprising a surface-mounted component installed on that surface of the electrically insulating substrate from which the protruding electronic component protrudes.

The 5^{th} aspect of the present invention is the electronic component-containing module according to the 1^{st} aspect of the present invention, further comprising a heat dissipating device installed on that part of the protruding electronic component which protrudes from the surface of the electrically insulating substrate.

The 6^{th} aspect of the present invention is a stacked electronic component module constructed by stacking electronic component-containing modules, comprising:

the electronic component-containing module according to the 1^{st} aspect of the present invention as an electronic component-containing module in at least one layer, wherein

a through-hole or a recess is provided in a surface of another electronic component-containing module opposite the electronic component-containing module in at least one layer to accommodate the protruding part of the protruding electronic component.

The 7^{th} aspect of the present invention is the electronic component-containing module according to the 1^{st} aspect of the present invention, comprising a printed board bonded to at least one surface of the electrically insulating substrate.

The 8^{th} aspect of the present invention is the electronic component-containing module according to the 7^{th} aspect of the present invention, wherein:

the printed board has a hole tailored to shape of the protruding electronic component; and

the protruding electronic component is exposed from the printed board via the hole.

The 9^{th} aspect of the present invention is the electronic component-containing module according to the 8^{th} aspect of the present invention, comprising mounting terminals installed on that surface of the printed board which has the hole.

The 10^{th} aspect of the present invention is the electronic component-containing module according to the 8^{th} aspect of the present invention, wherein the protruding electronic component is installed in a through-hole or a recess of the electrically insulating substrate, the through-hole or the recess having a shape corresponding to the hole in the printed board.

The 11^{th} aspect of the present invention is the electronic component-containing module according to the 10^{th} aspect of the present invention, wherein at least one of the electronic components other than the protruding electronic component is installed in the through-hole or the recess.

The 12^{th} aspect of the present invention is the electronic component-containing module according to the 10^{th} aspect of the present invention, comprising one or more electrodes for external electrical connection, the electrode being installed at least either on an inner wall of the hole in the printed board or on an inner wall of the through-hole or the recess in the electrically insulating substrate.

The 13^{th} aspect of the present invention is a manufacturing method for an electronic component-containing module, comprising:

forming at least a stacked structure of a first die release carrier, a second die release carrier, and an electrically insulating substrate, where a plurality of electronic components including at least one particular electronic component taller than the other electronic components are installed on a surface of the first die release carrier, the second die release carrier has a predetermined through-hole or recess tailored to shape and size of top of the particular electronic component at a location corresponding to a placement location of the particular electronic component, the electrically insulating substrate has a through-hole tailored to shape and size of the particular electronic component and a recess tailored to shape and size of the electronic component other than the particular electronic component, and forming the stacked structure by performing an alignment such that the electrically insulating substrate will be sandwiched between the first die release carrier and the second die release carrier, that the particular electronic component will be passed through the through-hole in the electrically insulating substrate, and that the top of the particular electronic component will be passed through the through-hole in the second die release carrier or fitted in the recess;

pressing and heating the stacked structure from outside both the first die release carrier and the second die release carrier using press dies; and

removing the first die release carrier and the second die release carrier from the stacked structure after the pressing and heating.

The 14^{th} aspect of the present invention is the manufacturing method for an electronic component-containing module according to the 13^{th} aspect of the present invention, wherein the particular electronic component protrudes from at least one surface of the electrically insulating substrate.

The 15^{th} aspect of the present invention is a manufacturing method for an electronic component-containing module, comprising:

forming at least a stacked structure of a first die release carrier, a second die release carrier, and an electrically insulating substrate, where at least one particular electronic component group made up of a plurality of electronic components is stacked on a surface of the first die release carrier, the second die release carrier has a predetermined through-hole or recess tailored to shape and size of top of the particular electronic component group at a location corresponding to a placement location of the particular electronic component group, the electrically insulating substrate has a through-hole tailored to shape and size of the particular electronic component group, and forming the stacked structure by performing an alignment such that the electrically insulating substrate will be sandwiched between the first die release carrier and the second die release carrier, that the particular electronic component group will be passed through the through-hole in the electrically insulating substrate, and that the top of the particular electronic component group will be passed through the through-hole in the second die release carrier or fitted in the recess;

pressing and heating the stacked structure from outside both the first die release carrier and the second die release carrier using press dies; and

removing the first die release carrier and the second die release carrier from the stacked structure after the pressing and heating.

The 16^{th} aspect of the present invention is the manufacturing method for an electronic component-containing module according to the 13^{th} aspect of the present invention, wherein:

the second die release carrier has the through-hole tailored to the shape and size of the top of the particular electronic component at the location corresponding to the placement location of the particular electronic component or the particular electronic component group;

the press die which heats and presses the stacked structure from outside the second die release carrier has a recess tailored to the shape of the top of the particular electronic component or the particular electronic component group; and

the press die heats and presses the stacked structure by abutting against the second die release carrier in such a way as to align the recess with the through-hole in the second die release carrier.

The 17^{th} aspect of the present invention is the manufacturing method for an electronic component-containing module according to the 15^{th} aspect of the present invention, wherein:

the second die release carrier has the through-hole tailored to the shape and size of the top of the particular electronic component at the location corresponding to the placement location of the particular electronic component or the particular electronic component group;

the press die which heats and presses the stacked structure from outside the second die release carrier has a recess tailored to the shape of the top of the particular electronic component or the particular electronic component group; and

the press die heats and presses the stacked structure by abutting against the second die release carrier in such a way as to align the recess with the through-hole in the second die release carrier.

The 18^{th} aspect of the present invention is a manufacturing method for an electronic component-containing module, comprising:

forming a stacked structure of a first die release carrier, a second die release carrier, and an electrically insulating substrate, where a plurality of electronic components is installed on the first die release carrier, the electrically insulating substrate has a first recess tailored to shape and size of the plurality of electronic components as well as a through-hole or a second recess tailored to shape and size of at least one particular electronic component, and forming the stacked structure by performing an alignment such that the electrically insulating substrate will be sandwiched between the first die release carrier and the second die release carrier;

pressing and heating the stacked structure from outside both the first die release carrier and the second die release carrier using press dies;

removing the first die release carrier and the second die release carrier from the stacked structure after the pressing and heating; and

mounting the particular electronic component in the through-hole or the second recess of the electrically insulating substrate after the removal of the first die release carrier and the second die release carrier.

The 19^{th} aspect of the present invention is the manufacturing method for an electronic component-containing module according to the 18^{th} aspect of the present invention, wherein the particular electronic component protrudes from at least one surface of the electrically insulating substrate.

The 20^{th} aspect of the present invention is a manufacturing method for an electronic component-containing module, comprising:

forming a stacked structure of a first die release carrier on which a plurality of electronic components are installed, a second die release carrier, and an electrically insulating substrate which has a through-hole or a recess by performing an alignment such that the electrically insulating substrate will be sandwiched between the first die release carrier and the second die release carrier;

pressing and heating the stacked structure from outside both the first die release carrier and the second die release carrier using press dies;

removing the first die release carrier and the second die release carrier from the stacked structure after the pressing and heating; and

mounting a particular electronic component group made up of a plurality of electronic components stacked together in the through-hole or the recess of the electrically insulating substrate after the removal of the first die release carrier and the second die release carrier.

The 21^{th} aspect of the present invention is the manufacturing method for an electronic component-containing module according to the 18^{th} aspect of the present invention, wherein:

the through-hole tailored to the shape and size of the particular electronic component or the particular electronic component group is formed in the electrically insulating substrate; and

the through-hole is formed at a location corresponding to part of the plurality of electronic components.

The 22^{nd} aspect of the present invention is the manufacturing method for an electronic component-containing module according to the 20^{th} aspect of the present invention, wherein:

the through-hole tailored to the shape and size of the particular electronic component or the particular electronic component group is formed in the electrically insulating substrate; and

the through-hole is formed at a location corresponding to part of the plurality of electronic components.

As described above, the present invention can reduce the thickness of the electrically insulating substrate and thereby reduce the overall size of the electronic component-containing module.

### BRIEF DESCRIPTION OF THE DRAWINGS

FIG. 1 is a sectional view showing an electronic component-containing module according to a first embodiment of the present invention;

FIG. 2 is a sectional view showing a variation of the electronic component-containing module according to the first embodiment of the present invention;

FIG. 3 is a sectional view showing a variation of the electronic component-containing module according to the first embodiment of the present invention;

FIG. 4(A) is a process-specific sectional view illustrating a preferred manufacturing method for the electronic component-containing module according to the first embodiment of the present invention;

FIG. 4(B) is a process-specific sectional view illustrating the preferred manufacturing method for the electronic component-containing module according to the first embodiment of the present invention;

FIG. 4(C) is a process-specific sectional view illustrating the preferred manufacturing method for the electronic component-containing module according to the first embodiment of the present invention;

FIG. 4(D) is a process-specific sectional view illustrating the preferred manufacturing method for the electronic component-containing module according to the first embodiment of the present invention;

FIG. 4(E) is a process-specific sectional view illustrating the preferred manufacturing method for the electronic component-containing module according to the first embodiment of the present invention;

FIG. 4(F) is a process-specific sectional view illustrating the preferred manufacturing method for the electronic component-containing module according to the first embodiment of the present invention;

FIG. 4(G) is a process-specific sectional view illustrating the preferred manufacturing method for the electronic component-containing module according to the first embodiment of the present invention;

FIG. 4(H) is a process-specific sectional view illustrating the preferred manufacturing method for the electronic component-containing module according to the first embodiment of the present invention;

FIG. 4(I) is a process-specific sectional view illustrating the preferred manufacturing method for the electronic component-containing module according to the first embodiment of the present invention;

FIG. 5(A) is a process-specific sectional view illustrating a preferred manufacturing method for an electronic component-containing module according to a second embodiment of the present invention;

FIG. 5(B) is a process-specific sectional view illustrating the preferred manufacturing method for the electronic component-containing module according to the second embodiment of the present invention;

FIG. 5(C) is a process-specific sectional view illustrating the preferred manufacturing method for the electronic component-containing module according to the second embodiment of the present invention;

FIG. 5(D) is a process-specific sectional view illustrating the preferred manufacturing method for the electronic component-containing module according to the second embodiment of the present invention;

FIG. 5(E) is a process-specific sectional view illustrating the preferred manufacturing method for the electronic component-containing module according to the second embodiment of the present invention;

FIG. 6 is a sectional view showing an electronic component-containing module according to a third embodiment of the present invention;

FIG. 7 is a sectional view showing a variation of the electronic component-containing module according to the third embodiment of the present invention;

FIG. 8 is a sectional view showing a variation of the electronic component-containing module according to the third embodiment of the present invention;

FIG. 9 is a sectional view showing a variation of the electronic component-containing module according to the third embodiment of the present invention;

FIG. 10(A) is a process-specific sectional view illustrating a preferred manufacturing method for the electronic component-containing module according to the third embodiment of the present invention;

FIG. 10(B) is a process-specific sectional view illustrating the preferred manufacturing method for the electronic component-containing module according to the third embodiment of the present invention;

FIG. 10(C) is a process-specific sectional view illustrating the preferred manufacturing method for the electronic component-containing module according to the third embodiment of the present invention;

FIG. 10(D) is a process-specific sectional view illustrating the preferred manufacturing method for the electronic component-containing module according to the third embodiment of the present invention;

FIG. 10(E) is a process-specific sectional view illustrating the preferred manufacturing method for the electronic component-containing module according to the third embodiment of the present invention;

FIG. 10(F) is a process-specific sectional view illustrating the preferred manufacturing method for the electronic component-containing module according to the third embodiment of the present invention;

FIG. 11(A) is a process-specific sectional view illustrating a preferred manufacturing method for an electronic component-containing module according to a fourth embodiment of the present invention;

FIG. 11(B) is a process-specific sectional view illustrating the preferred manufacturing method for the electronic component-containing module according to the fourth embodiment of the present invention;

FIG. 11(C) is a process-specific sectional view illustrating the preferred manufacturing method for the electronic component-containing module according to the fourth embodiment of the present invention;

FIG. 11(D) is a process-specific sectional view illustrating the preferred manufacturing method for the electronic component-containing module according to the fourth embodiment of the present invention;

FIG. 11(E) is a process-specific sectional view illustrating the preferred manufacturing method for the electronic component-containing module according to the fourth embodiment of the present invention;

FIG. 11(F) is a process-specific sectional view illustrating the preferred manufacturing method for the electronic component-containing module according to the fourth embodiment of the present invention;

FIG. 11(G) is a process-specific sectional view illustrating the preferred manufacturing method for the electronic component-containing module according to the fourth embodiment of the present invention;

FIG. 11(H) is a process-specific sectional view illustrating the preferred manufacturing method for the electronic component-containing module according to the fourth embodiment of the present invention;

FIG. 11(I) is a process-specific sectional view illustrating the preferred manufacturing method for the electronic component-containing module according to the fourth embodiment of the present invention;

FIG. 11(J) is a process-specific sectional view illustrating the preferred manufacturing method for the electronic component-containing module according to the fourth embodiment of the present invention;

FIG. 12(A) is a sectional view showing a stacked electronic component module according to a fifth embodiment of the present invention;

FIG. 12(B) is a sectional view showing another example of the stacked electronic component module according to the fifth embodiment of the present invention;

FIG. 13(A) is a sectional view showing a configuration example in which printed wiring boards are used in the electronic component-containing module according to the present invention;

FIG. 13(B) is a sectional view showing a configuration example in which printed wiring boards are used in the stacked electronic component module according to the present invention;

FIG. 14 is a sectional view showing a configuration example in which printed wiring boards are used in the electronic component-containing module according to the present invention;

FIG. 15 is a plan view showing a configuration example in which printed wiring boards are used in the electronic component-containing module according to the present invention;

FIG. 16 is an exploded view showing a configuration example in which printed wiring boards are used in the electronic component-containing module according to the present invention;

FIG. 17(A) is a sectional view showing a manufacturing process of a conventional electronic component-containing module;

FIG. 17(B) is a sectional view showing a manufacturing process of the conventional electronic component-containing module;

FIG. 17(C) is a sectional view showing a manufacturing process of the conventional electronic component-containing module; and

FIG. 17(D) is a sectional view showing a manufacturing process of the conventional electronic component-containing module.

### DESCRIPTION OF SYMBOLS

101, 201, 301, 401, 501, 601, 701, 801, 901, 1001, 1101, 1201, 1301, 1401: Electronic component-containing module
102, 302, 402, 502, 602, 802, 902, 1002: First electronic component
103, 403, 503, 603, 903, 1003, 1103, 1403: Second electronic component
104, 404, 504, 604, 904: Electrically insulating substrate
105a, 105b, 405a, 405b, 505a, 505b, 605a, 605b, 1005a, 1005b, 1105a, 1105b, 1405a, 1405b: Wiring pattern
106, 406, 506, 606, 1006, 1106, 1406: Inner via
220, 720: Electronic component
321, 821: Heat dissipating device
407a, 407b, 507a, 507b, 1007a, 1007b, 1107a, 1107b, 1407a, 1407b: Die release carrier
408, 1008: Opening
409a, 409b, 509a, 509b, 1009a, 1009b, 1109a, 1109b: Void
410a, 410b, 510a, 510b, 1010a, 1010b, 1110a, 1110b: Pressing die
411, 1011: Surface depression
1012, 1112: Adhesive
1316a, 1316b, 1316c: Printed wiring board

### PREFERRED EMBODIMENTS OF THE INVENTION

Embodiments of the present invention will be described below with reference to the drawings.

### First Embodiment

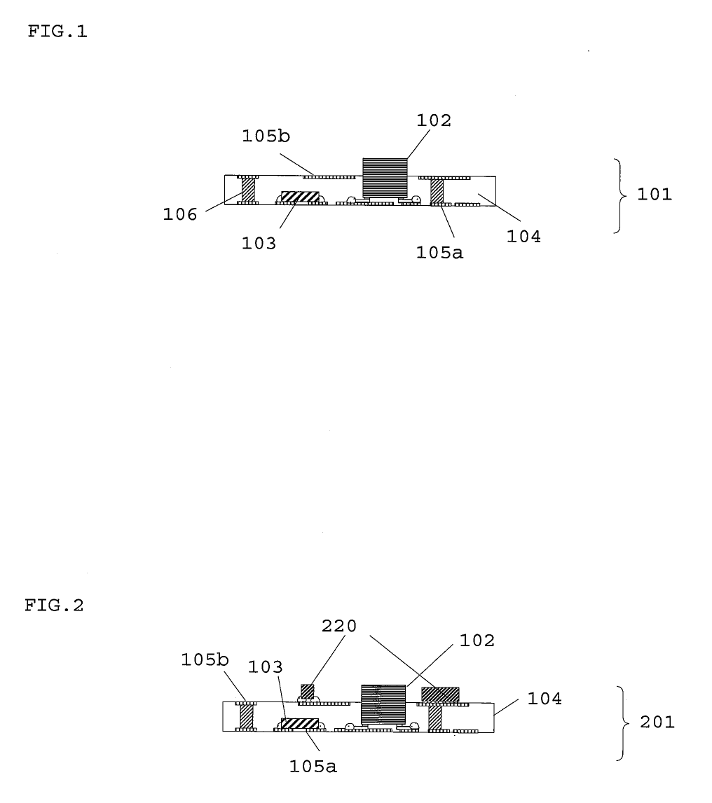

FIG. 1 is a sectional view showing an electronic component-containing module according to a first embodiment of the present invention. As shown in FIG. 1, the electronic component-containing module 101 according to the first embodiment of the present invention has a configuration in which a first electronic component 102 and second electronic component 103 are embedded in an electrically insulating substrate 104, with the first electronic component 102 protruding partially from a surface of the electrically insulating substrate 104 and the second electronic component 103 being contained entirely in the electrically insulating substrate 104.

The first electronic component 102, which is mounted on a wiring pattern 105a, protrudes partially from the electrically insulating substrate 104, being taller than the second electronic component 103 among the electronic components embedded in the electrically insulating substrate 104. On the other hand, the second electronic component 103, which is shorter in height than the first electronic component 102, is contained in the electrically insulating substrate 104.

The first electronic component 102 and second electronic component 103 are connected to the wiring pattern 105a, for example, by flip-chip mounting (which is a known technique) if they are bare chips such as LSIs or DRAMs, or by soldering if they are component packages such as BGAs or CSPs or if they are chip components such as resistors or capacitors.

Wiring patterns 105a and 105b are formed on opposite sides of the electrically insulating substrate 104 and are interconnected electrically via an inner via 106 formed by passing through the electrically insulating substrate 104.

The electrically insulating substrate 104 is made of a thermosetting resin (such as an epoxy resin, phenolic resin, or polyimide resin), which may contain an inorganic filler such as SiO₂ or may be entirely free of inorganic fillers. Preferably, the material of the electrically insulating substrate 104 has enough heat resistance to withstand high temperatures during a reflow process (e.g., enough heat resistance to withstand 240° C. for 10 seconds).

According to the first embodiment, in particular, it is preferable to use a compound containing 70 to 95 wt % of inorganic filler and 5 to 30 wt % of resin composite as the material of the electrically insulating substrate 104. This also applies to the other embodiments described below.

The wiring patterns 105a and 105b are made of copper foil or conductive resin composite. For example, the copper foil, when used, may be 12 to 35 μm thick, being produced by electrolytic plating. Desirably, an abutting surface of the copper foil which abuts the electrically insulating substrate is roughened to improve adhesion to the electrically insulating substrate. Also, to improve adhesion and oxidation resistance, the copper foil surface may be subjected to coupling treatment or plated with tin, zinc, or nickel.

The inner via 106 is made, for example, of a thermosetting conductive substance. The thermosetting conductive substance may be, for example, a conductive resin composite mixed with metal particles and a thermosetting resin. The metal particles may be gold, silver, copper, or nickel, which are desirable because of their high conductivity. Copper is particularly desirable because of its high conductivity and low migration. The thermosetting resin may be, for example, an epoxy resin, phenolic resin, or cyanate resin, and the epoxy resin is particularly desirable because of its high heat resistance.

Incidentally, in the above configuration, the electronic component-containing module 101 is an example of the electronic component-containing module according to the present invention. The first electronic component 102 and second electronic component 103 are examples of the plurality of electronic components according to the present invention. Also, the first electronic component 102 is an example of the protruding electronic component according to the present invention.

In the electronic component-containing module according to the first embodiment with the above configuration, when a tall component such as the first electronic component 102 and a short component such as the second electronic component 103 are embedded in the electrically insulating substrate 104, since there is no need to set the thickness of the electrically insulating substrate 104 to the thickness of the tall component, it is possible to reduce the thickness of the electrically insulating substrate 104 and thereby reduce the overall size of the electronic component-containing module 101.

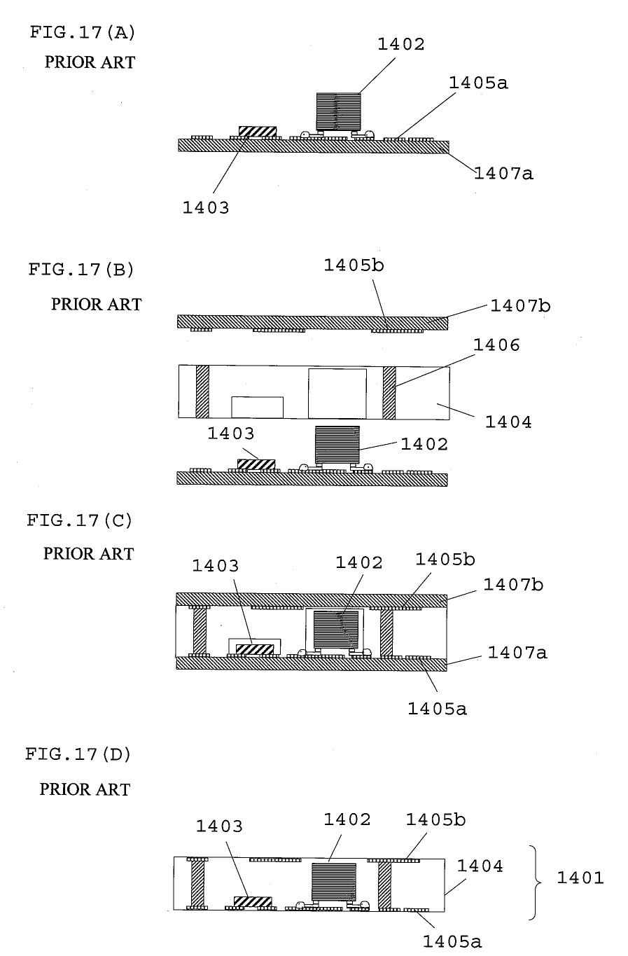

Also, as shown in FIG. 2, electronic components 220 can be mounted further on the electronic component-containing module. This allows more components to be mounted in the same volume as the electronic component-containing module 1401 shown in FIG. 17, making it possible to provide an electronic component-containing module 201 which offers higher functionality.

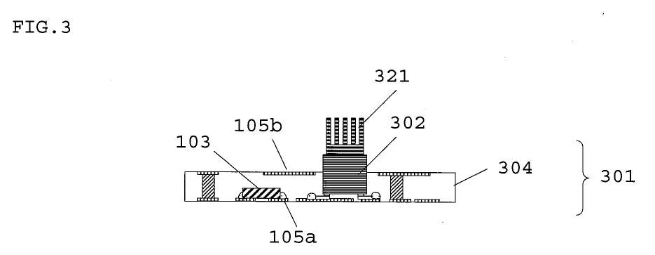

Also, as shown in FIG. 3, if a heat dissipating device 321 is attached to protruding part of a first electronic component 302, heat can be dissipated efficiently. As the heat dissipating device 321, fins are preferable in terms of heat dissipation efficiency, but a sheet-type device made of a high thermally conductive material such as a copper foil may be used as well.

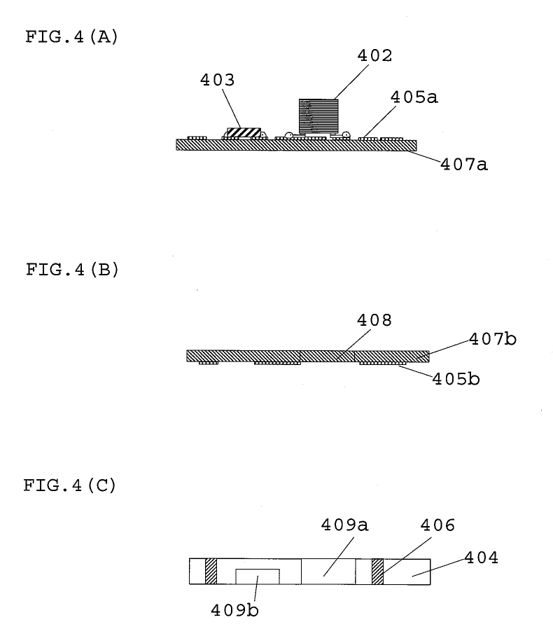

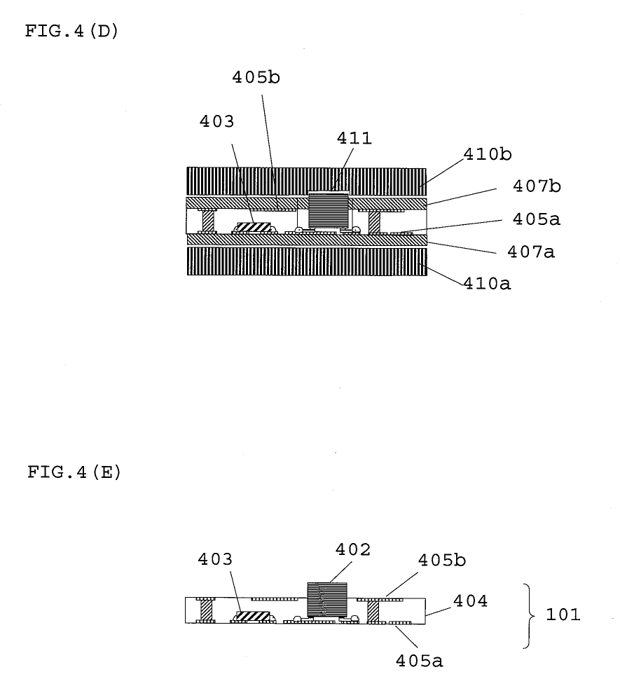

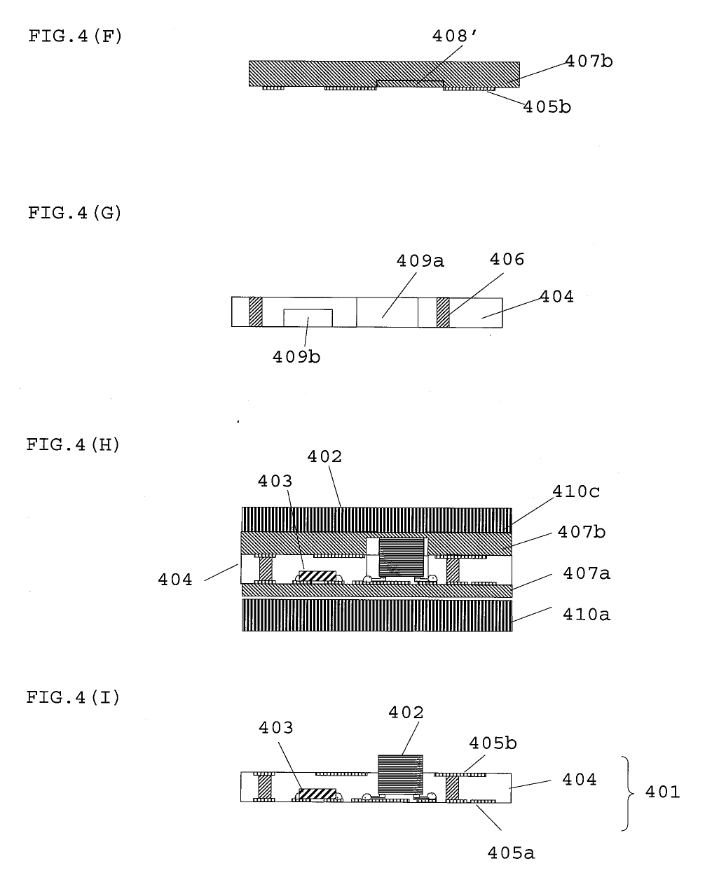

Next, a manufacturing method for an electronic component-containing module according to the first embodiment of the present invention will be described below with reference to FIGS. 4(A) to 4(E).

First, as shown in FIG. 4(A), a first electronic component 402 and second electronic component 403 are mounted on a wiring pattern 405a formed on a first die release carrier 407a.

As measured from a surface of the wiring pattern 405a, the first electronic component 402 is taller than the second electronic component 403, and the second electronic component 403 is shorter than the first electronic component 402.

Regarding a mounting method, the first electronic component 402 and second electronic component 403 are connected to the wiring pattern 405a, for example, by flip-chip mounting (which is a known technique) if they are bare chips such as LSIs or DRAMs, or by soldering if they are component packages such as BGAs or CSPs or if they are chip components such as resistors or capacitors.

Next, as shown in FIG. 4(B), an opening 408 is formed, passing from one side to the other, in a second die release carrier 407b on which a wiring pattern 405b has been formed. The opening 408, in which the first electronic component is housed in a subsequent process, has shape and size suitable to accommodate the first electronic component 402. As an example, it is preferable that dimensions of the opening 408 are 0.05 mm or more larger than dimensions of the first electronic component 402.

Next, as shown in FIG. 4(C), an inner via 406 and cavities 409a and 409b are formed on an uncured electrically insulating substrate 404 thinner than the height of the first electronic component 402 and thicker than the height of the second electronic component 403.

The inner via 406 is formed to have a diameter of 0.15 mm by laser or punching and filled with a conductive resin paste by printing.

The cavities 409a and 409b are formed by laser or punching as in the case of the inner via 406.

The cavity 409a has shape and size suitable to accommodate the first electronic component 402. Furthermore, the cavity 409a is formed as a through-hole passing through the electrically insulating substrate 404 from one surface to the other surface corresponding to the thickness of the first electronic component 402. On the other hand, the cavity 409b has shape and size suitable to accommodate the second electronic component 403. Furthermore, the cavity 409b is formed as a recess in the electrically insulating substrate 404 corresponding to the thickness of the second electronic component 403.

Next, as shown in FIG. 4(D), the first die release carrier 407a, electrically insulating substrate 404, and second die release carrier 407b are aligned and stacked together, to form a stacked structure, in such a way that the wiring pattern 405a formed on the first die release carrier 407a and the wiring pattern 405b formed on the second die release carrier 407b will come into contact with the inner via 406, that the first electronic component 402 will pass through the cavity 409a in the electrically insulating substrate 404 and the opening 408 in the second die release carrier 407b, and that the second electronic component 403 will fit in the cavity 409b.

By hot-pressing the stacked structure from outside with the first die release carrier 407a and second die release carrier 407b abutted against press dies 410a and 410b, respectively, the first electronic component 402 and second electronic component 403 are built into the electrically insulating substrate 404, and the wiring pattern 405a and wiring pattern 405b are electrically interconnected via the inner via 406.

The hot pressing is done at temperatures ranging from 70 to 300° C. and at pressures ranging from 0.1 to 10 MPa, and preferably at temperatures ranging from 150 to 250° C. and at pressures ranging from 0.5 to 5 MPa. During the hot pressing, the uncured electrically insulating substrate 404 has its viscosity reduced once, and then cures after the electronic components to be embedded are buried completely. Consequently, the wiring patterns formed on the first die release carrier 407a and second die release carrier 407b are embedded in the electrically insulating substrate 404 and bonded.

Preferably, the press die 410b has a surface depression 411 which has shape and size suitable to accommodate top of the first electronic component 402, i.e., part which protrudes from the surface of the substrate after completion of the module. As the top of the first electronic component 402 fits in the surface depression 411, the other parts of the press die 410b abut the electrically insulating substrate 404, causing pressure to be applied uniformly to the electrically insulating substrate 404.

Next, as shown in FIG. 4(E), the first die release carrier 407a and second die release carrier 407b are removed to obtain the electronic component-containing module 101 according to the first embodiment shown in FIG. 1.

Subsequently, the electronic components 220 are mounted on the surface of the electronic component-containing module 101 to obtain the high-density, high-functionality electronic component-containing module 201 shown in FIG. 2.

Also, as shown in FIG. 3, by mounting the heat dissipating device 321 on the protruding part of the first electronic component 302, it is possible to dissipate heat efficiently. As the heat dissipating device 321, fins are preferable in terms of heat dissipation efficiency, but a sheet-type device made of a high thermally conductive material such as a copper foil may be used as well.

In the above processes, the first die release carrier 407a is an example of the first die release carrier according to the present invention and the second die release carrier 407b is an example of the second die release carrier according to the present invention. Also, the electrically insulating substrate 404 is an example of the electrically insulating substrate according to the present invention. The press dies 410a and 410b are examples of the press dies according to the present invention.

Also, the first electronic component 402 is an example of the particular electronic component according to the present invention and second electronic component 403 is an example of the other electronic component according to the present invention. Also, the cavity 409a in the electrically insulating substrate 404 is an example of the through-hole according to the present invention and the cavity 409b is an example of the recess according to the present invention. Also, the opening 408 in the second die release carrier 407b is an example of the predetermined through-hole according to the present invention. Also, the surface depression 411 of the press die 410b is an example of the recess according to the present invention.

However, the present invention is not limited to the above processes. Although it has been stated that the second die release carrier 407b has the opening 408 as the through-hole according to the present invention, the second die release carrier 407b may have a recess 408′ as the recess according to the present invention as shown in FIG. 4(F). The recess 408′ is tailored to shape and size of the first electronic component 402 and is deep enough for the top of the first electronic component 402 to fit in.

The use of the second die release carrier 407b to produce a stacked structure (shown in FIG. 4(G)) sandwiching the electrically insulating substrate 404 (the same as the one shown in FIG. 4(C)) makes it possible to use a flat press die 410c without a surface depression (shown in FIG. 4(H)) as a press die in pressing and heating the stacked structure from above and below. This reduces production costs of the press dies 410.

### Second Embodiment

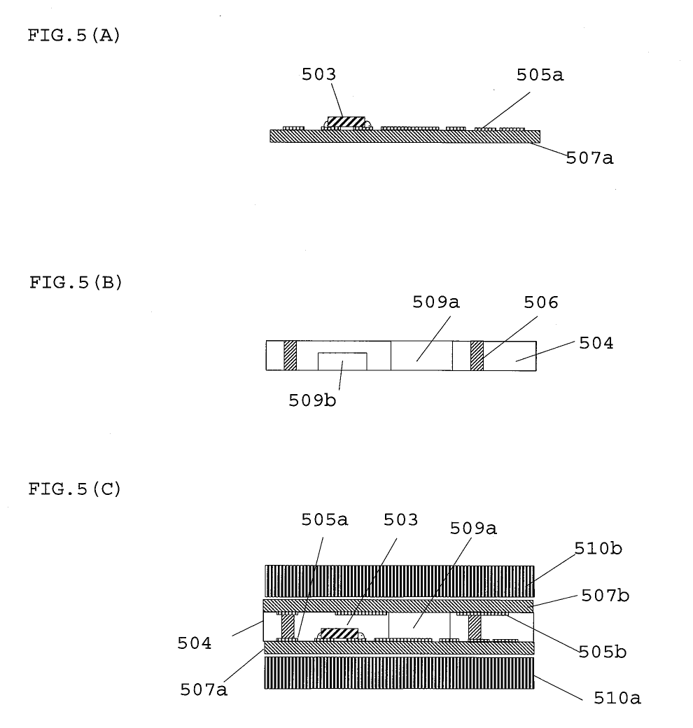

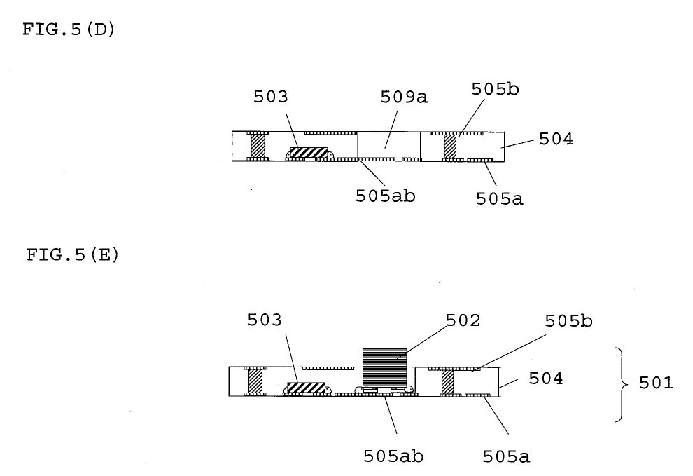

FIGS. 5(A) to 5(E) are sectional views showing a manufacturing method of an electronic component-containing module according to a second embodiment of the present invention. The manufacturing method according to the second embodiment is an alternative to the manufacturing method of the electronic component-containing module according to the first embodiment and differs from the first embodiment in that a first electronic component 502 is mounted on a wiring pattern 505a after a hot-pressing process.

In the second embodiment, members corresponding to those of the electronic component-containing module according to the first embodiment are made of the same materials and subjected to the same treatment as the first embodiment.

A manufacturing method for the electronic component-containing module according to the second embodiment will be described below with reference to FIGS. 5(A) to 5(E).

First, as shown in FIG. 5(A), a second electronic component 503 is mounted on a wiring pattern 505a formed on a first die release carrier 507a. Regarding a mounting method, the second electronic component 503 is connected to the wiring pattern 505a, for example, by flip-chip mounting (which is a known technique) if the second electronic component 503 is a bare chip such as an LSI or DRAM, or by soldering if the second electronic component 503 is a component package such as a BGA or CSP or if the second electronic component 503 is a chip component such as a resistor or capacitor.

Next, as shown in FIG. 5(B), an inner via 506 and cavities 509a and 509b are formed on an electrically insulating substrate 504 thinner than the first electronic component 502 to be mounted later and thicker than the second electronic component 503. The inner via 506 is formed to have a diameter of 0.15 mm by laser or punching and filled with a conductive resin paste by printing.

The cavities 509a and 509b are formed by laser or punching as in the case of the inner via.

The cavity 509a has shape and size suitable to accommodate the first electronic component 502 to be mounted later. Furthermore, the cavity 509a is formed as a through-hole passing through the electrically insulating substrate 504 from one surface to the other surface corresponding to the thickness of the first electronic component 502. On the other hand, the cavity 509b has shape and size suitable to accommodate the second electronic component 503. Furthermore, the cavity 509b is formed as a recess in the electrically insulating substrate 504 corresponding to the thickness of the second electronic component 503.

Preferably, the cavity 509b, in which the first electronic component 502 is embedded after hot pressing, is processed to be 0.5 mm or more larger than dimension of the first electronic component 502, allowing for resin flow of the electrically insulating substrate during the hot pressing.

Next, as shown in FIG. 5(C), the first die release carrier 507a, electrically insulating substrate 504, and second die release carrier 507b are aligned and stacked together, to form a stacked structure, in such a way that the wiring pattern 505a formed on the first die release carrier 507a and the wiring pattern 505b formed on the second die release carrier 507b will come into contact with the inner via 506 and that the second electronic component 503 will fit in the cavity 509b.

By hot-pressing the stacked structure from outside with the first die release carrier 507a and second die release carrier 507b abutted against a pair of press dies 510a and 510b, respectively, the second electronic component 503 is built into the electrically insulating substrate 504, and the wiring pattern 505a and wiring pattern 505b are electrically interconnected via the inner via 506.

The hot pressing is done at temperatures ranging from 70 to 300° C. and at pressures ranging from 0.1 to 10 MPa, and preferably at temperatures ranging from 150 to 250° C. and at pressures ranging from 0.5 to 5 MPa. During the hot pressing, the uncured electrically insulating substrate 504 has its viscosity reduced once, and then cures after the second electronic component 503 to be embedded is buried completely. Consequently, the wiring patterns 505a and 505b formed on the first die release carrier 507a and the second die release carrier 507b, respectively, are embedded in the electrically insulating substrate 504 and bonded.

Next, as shown in FIG. 5(D), the first die release carrier 507a and second die release carrier 507b are removed. At this time, a wiring pattern 505ab which is part of the wiring pattern 505a has been placed on the electrically insulating substrate 504 so as to close the bottom of the cavity 509a after the removal.

Next, as shown in FIG. 5(E), the first electronic component 502 is placed in the cavity 509a and mounted on the wiring pattern 505ab of the wiring pattern 505a to obtain the electronic component-containing module 501.

Regarding a mounting method, as in the case of the second electronic component 503, the first electronic component 502 is connected to the wiring pattern 505a, for example, by flip-chip mounting (which is a known technique) if the first electronic component 502 is a bare chip such as an LSI or DRAM, or by soldering if the first electronic component 502 is a component package such as a BGA or CSP or if the first electronic component 502 is a chip component such as a resistor or capacitor.

In the above processes, the first die release carrier 507a is an example of the first die release carrier according to the present invention and the second die release carrier 507b is an example of the second die release carrier according to the present invention. Also, the electrically insulating substrate 504 is an example of the electrically insulating substrate according to the present invention. The press dies 510a and 510b are examples of the press dies according to the present invention.

Also, the first electronic component 502 is an example of the particular electronic component according to the present invention and the second electronic component 503 and wiring pattern 505a are examples of the plurality of electronic components according to the present invention. Also, the cavity 509a in the electrically insulating substrate 504 is an example of the through-hole according to the present invention and the cavity 509b is an example of the first recess according to the present invention.

The second embodiment, according to which the first electronic component 502 is mounted after the hot pressing, can omit forming an opening in the second die release carrier 507b, and thereby simplify processes, consequently improving productivity.

Since the hot-pressing process does not require a complicated press die with a surface depression, it is possible to reduce production costs of the press dies 510.

### Third Embodiment

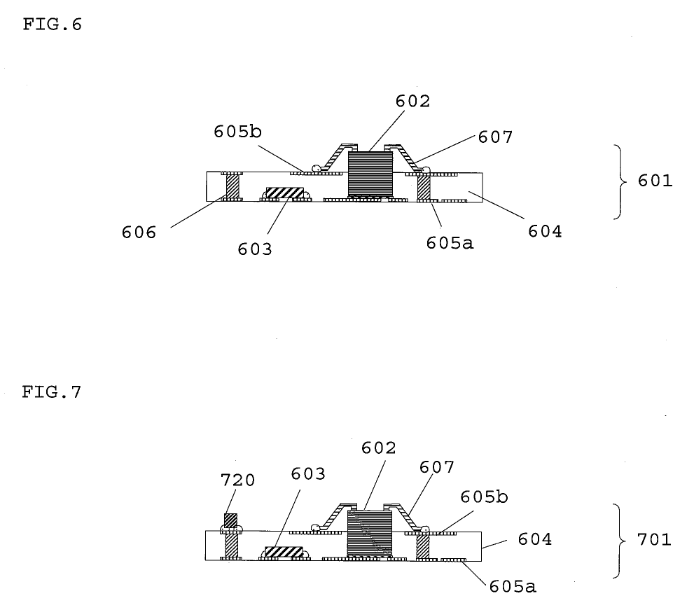

FIG. 6 is a sectional view showing a manufacturing method of an electronic component-containing module according to a third embodiment of the present invention.

In the third embodiment, members corresponding to those of the electronic component-containing module according to the first embodiment are made of the same materials and subjected to the same treatment as the first embodiment.

As shown in FIG. 6, the electronic component-containing module 601 according to the third embodiment has a configuration in which a first electronic component 602 and second electronic component 603 are embedded in an electrically insulating substrate 604, with the first electronic component 602 protruding partially from a surface of the electrically insulating substrate 604 and the second electronic component 603 being contained entirely in the electrically insulating substrate 604, as in the case of the first and second embodiments.

The third embodiment differs from the first and second embodiments in that the first electronic component 602 is connected to a wiring pattern on a surface which does not abut the electrically insulating substrate 604, i.e., the first electronic component 602 is connected to a wiring pattern 605b via wiring 607 outside the electrically insulating substrate 604.

Description will be given below. The first electronic component 602, which is mounted on a wiring pattern 605a, protrudes partially from the electrically insulating substrate 604, being taller in height than the second electronic component 603 among the electronic components embedded in the electrically insulating substrate 604. On the other hand, the second electronic component 603, which is shorter in height than the first electronic component 602, is contained in the electrically insulating substrate 604.

The first electronic component 602 and second electronic component 603 are connected, for example, by flip-chip mounting (which is a known technique) if they are bare chips such as LSIs or DRAMs, or by soldering if they are component packages such as BGAs or CSPs or if they are chip components such as resistors or capacitors.

The wiring patterns 605a and 605b are formed on opposite sides of the electrically insulating substrate 604 and are interconnected electrically via an inner via 606 formed by passing through the electrically insulating substrate 604.

The electrically insulating substrate 604 is made of a thermosetting resin (such as an epoxy resin, phenolic resin, or polyimide resin), which may contain an inorganic filler such as SiO₂ or may be entirely free of inorganic fillers. Preferably, the material of the electrically insulating substrate 604 has enough heat resistance to withstand high temperatures during a reflow process (e.g., enough heat resistance to withstand 240° C. for 10 seconds).

The wiring patterns 605a and 605b are made of copper foil or conductive resin composite. For example, the copper foil, when used, may be 12 to 35 μm thick, being produced by electrolytic plating. Desirably, an abutting surface of the copper foil which abuts the electrically insulating substrate is roughened to improve adhesion to the electrically insulating substrate. Also, to improve adhesion and oxidation resistance, the copper foil surface may be subjected to coupling treatment or plated with tin, zinc, or nickel.

The inner via 606 is made, for example, of a thermosetting conductive substance. The thermosetting conductive substance may be, for example, a conductive resin composite mixed with metal particles and a thermosetting resin. The metal particles may be gold, silver, copper, or nickel, which are desirable because of their high conductivity. Copper is particularly desirable because of its high conductivity and low migration. The thermosetting resin may be, for example, an epoxy resin, phenolic resin, or cyanate resin, and the epoxy resin is particularly desirable because of its high heat resistance.

Incidentally, in the above configuration, the electronic component-containing module 601 is an example of the electronic component-containing module according to the present invention. The first electronic component 602 and second electronic component 603 are examples of the plurality of electronic components according to the present invention. Also, the first electronic component 602 is an example of the protruding electronic component according to the present invention. The wiring pattern 605b is an example of the electrode according to the present invention and the wiring 607 is a means used to connect the protruding electronic component and electrode according to the present invention to the outside of the electrically insulating substrate.

In the electronic component-containing module according to the third embodiment with the above configuration, when a tall component such as the first electronic component 602 and a short component such as the second electronic component 603 are embedded in the electrically insulating substrate 604, since there is no need to set the thickness of the electrically insulating substrate 604 to the thickness of the tall component, it is possible to reduce the thickness of the electrically insulating substrate 604 and thereby reduce the overall size of the electronic component-containing module 601 as in the case of the first and second embodiments.

Furthermore, by ensuring electrical connection with the first electronic component 602 outside the electrically insulating substrate 604 using the wiring 607, the third embodiment can increase the number of embeddable electronic components and thereby increase packaging density.

Also, as shown in FIG. 7, an electronic component 720 can be mounted further on the electronic component-containing module. This allows more components to be mounted in the same volume as the electronic component-containing module 1401 shown in FIG. 17, making it possible to provide an electronic component-containing module 701 which offers higher functionality.

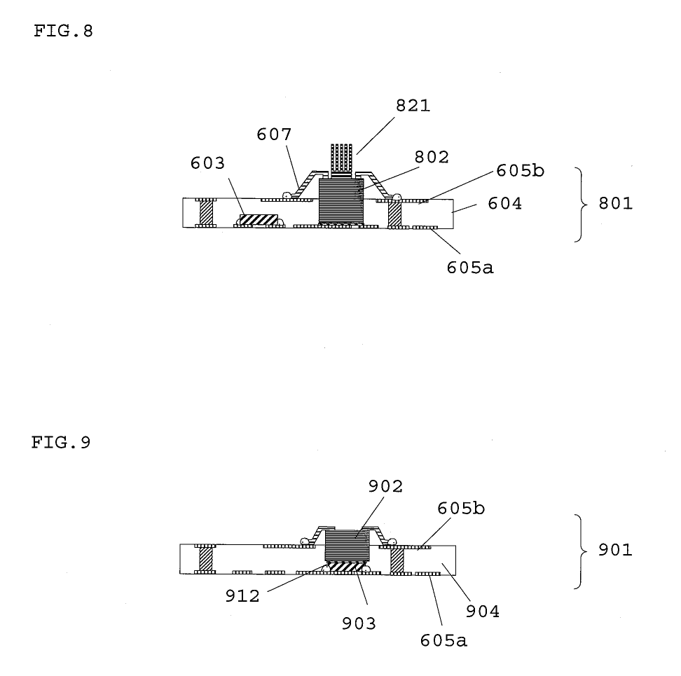

Also, as shown in FIG. 8, if a heat dissipating device 821 is attached to protruding part of a first electronic component 802, heat can be dissipated efficiently. As the heat dissipating device 821, fins are preferable in terms of heat dissipation efficiency, but a sheet-type device made of a high thermally conductive material such as a copper foil may be used as well.

Also, as shown in FIG. 9, a first electronic component 902 and second electronic component 903 may be stacked via an adhesive 912 in an electrically insulating substrate 904. This will give the electrically insulating substrate 904 more space to embed electronic components, resulting in a higher-density, electronic component-containing module which offers more functions. Also, a second electronic component similar to the second electronic component 103 in FIG. 1 may be installed additionally in the electrically insulating substrate 904.

Incidentally, in the configuration shown in FIG. 9, there is an advantage that the first electronic component 902 serving as the protruding electronic component according to the present invention may be thinner than the electrically insulating substrate 904.

In this way, the protruding electronic component according to the present invention needs only to protrude partially from the surface of the substrate in the completed electronic component-containing module, and height of the protruding electronic component as a whole is not limited by the thickness of the substrate.

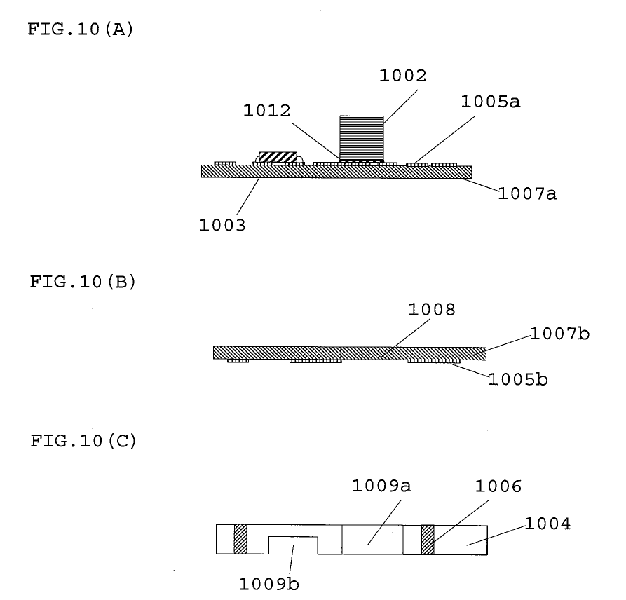

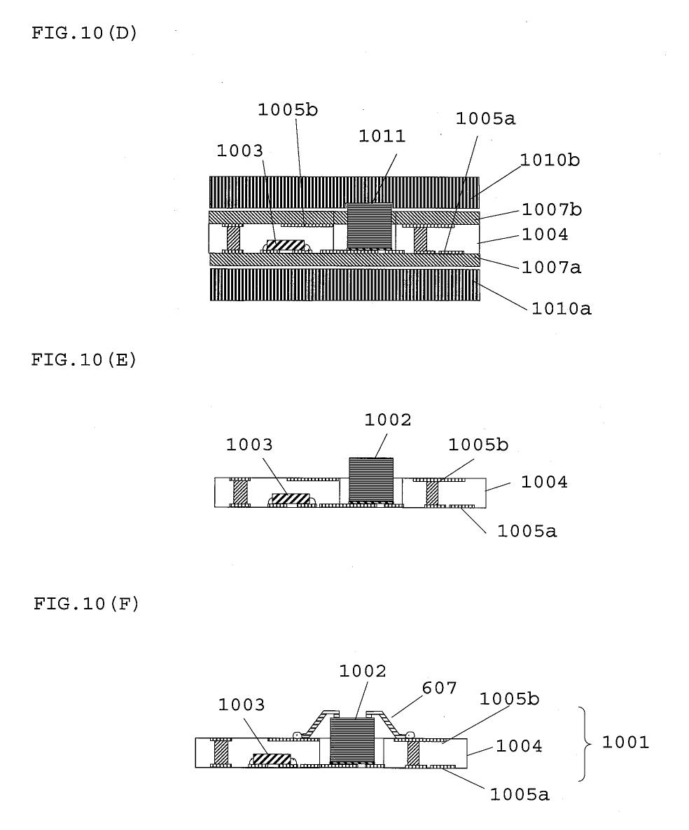

Next, a manufacturing method for the electronic component-containing module according to the third embodiment will be described below with reference to FIGS. 10(A) to 10(F).

Processes shown in FIGS. 10(A) to 10(E) are practically the same as the processes according to the first embodiment shown in FIGS. 4(A) to 4(E), respectively.

Specifically, in FIG. 10(A), a first electronic component 1002 is pasted onto a first die release carrier 1007a. The pasting is achieved by means of an adhesive 1012. A method which mounts the first electronic component 1002 with a sheet-type adhesive attached in advance provides high productivity. Suitable materials for the adhesive 1012 include thermosetting epoxy, polyimide, and acrylic resins. It is preferable to use a material which provides high heat resistance.

Next, a second electronic component 1003 is mounted on a wiring pattern 1005a formed on the first die release carrier 1007a.

The second electronic component 1003 is connected to the wiring pattern 1005a, for example, by flip-chip mounting (which is a known technique) if the second electronic component 1003 is a bare chip such as an LSI or DRAM, or by soldering if the second electronic component 1003 is a component package such as a BGA or CSP or if the second electronic component 1003 is a chip component such as a resistor or capacitor.

Next, as shown in FIG. 10(B), an opening 1008 is formed, passing from one side to the other, in a second die release carrier 1007b on which a wiring pattern 1005b has been formed. The opening 1008, in which the first electronic component 1002 is housed in a subsequent process, has shape and size suitable to accommodate the first electronic component 1002. As an example, it is preferable that dimensions of the opening 1008 are 0.05 mm or more larger than dimensions of the first electronic component 1002.

Next, as shown in FIG. 10(C), an inner via 1006 and cavities 1009a and 1009b are formed on an electrically insulating substrate 1004 thinner than the first electronic component 1002 and thicker than the second electronic component 1003.

The inner via 1006 is formed to have a diameter of 0.15 mm by laser or punching and filled with a conductive resin paste by printing.

The cavities 1009a and 1009b are formed by laser or punching as in the case of the inner via 1006.

The cavity 1009a has shape and size suitable to accommodate the first electronic component 1002. Furthermore, the cavity 1009a is formed as a through-hole passing through the electrically insulating substrate 1004 from one surface to the other surface corresponding to the thickness of the first electronic component 1002. On the other hand, the cavity 1009b has shape and size suitable to accommodate the second electronic component 1003. Furthermore, the cavity 1009b is formed as a recess in the electrically insulating substrate 1004 corresponding to the thickness of the second electronic component 1003.

Next, as shown in FIG. 10(D), the first die release carrier 1007a, electrically insulating substrate 1004, and second die release carrier 1007b are aligned and stacked together, to form a stacked structure, in such a way that the wiring pattern 1005a formed on the first die release carrier 1007a and the wiring pattern 1005b formed on the second die release carrier 1007b will come into contact with the inner via 1006, that the first electronic component 1002 will pass through the cavity 1009a in the electrically insulating substrate 1004 and the opening 1008 in the second die release carrier 1007b, and that the second electronic component 1003 will fit in the cavity 1009b.

By hot-pressing the stacked structure from outside with the first die release carrier 1007a and second die release carrier 1007b abutted against press dies 1010a and 1010b, respectively, the first electronic component 1002 and second electronic component 1003 are built into the electrically insulating substrate 1004, and the wiring pattern 1005a and wiring pattern 1005b are electrically interconnected via the inner via 1006.

The hot pressing is done at temperatures ranging from 70 to 300° C. and at pressures ranging from 0.1 to 10 MPa, and preferably at temperatures ranging from 150 to 250° C. and at pressures ranging from 0.5 to 5 MPa. During the hot pressing, the uncured electrically insulating substrate 1004 has its viscosity reduced once, and then cures after the electronic components to be embedded are buried completely. Consequently, the wiring patterns formed on the first die release carrier 1007a and second die release carrier 1007b are embedded in the electrically insulating substrate 1004 and bonded.

Since the press die 1010b has a surface depression 1011 suitable to accommodate the protruding part of the first electronic component 1002 as in the case of the press die 410b according to the first embodiment, the press die 1010b can apply pressure uniformly to the substrate in spite of the protrusion of the first electronic component 1002.

Next, as shown in FIG. 10(E), the first die release carrier 1007a and second die release carrier 1007b are removed.

Next, as shown in FIG. 10(F), the first electronic component 1002 is connected to a wiring pattern 1005b via wiring 607.

The first electronic component 1002 is connected, for example, by wire-bonding if the first electronic component 1002 is an LSI, DRAM or another bare chip or a BGA, CSP, or the like which does not have a lead frame, or by soldering if the first electronic component 1002 has a lead frame.

Incidentally, to produce a stacked electronic component module shown in FIG. 9 with the first electronic component 902 stacked on the second electronic component 903, the cavity 1009b needed to mount the second electronic component 1003 is omitted from the electrically insulating substrate 1004 in the processes in FIGS. 10(A) to 10(F) and a stack of the first electronic component 902 and second electronic component 903 is mounted in advance instead of the first electronic component 1002 in FIG. 10(A). In that case, the stack of the first electronic component 902 and second electronic component 903 corresponds to the particular electronic component group according to the present invention. When a second electronic component such as the second electronic component 1003 is used, the cavity 1009b is not omitted.

### Fourth Embodiment

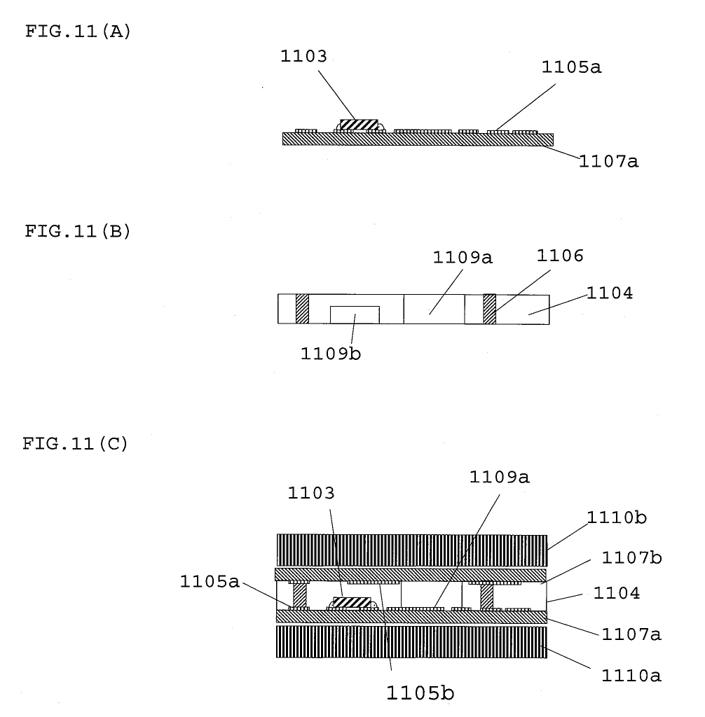

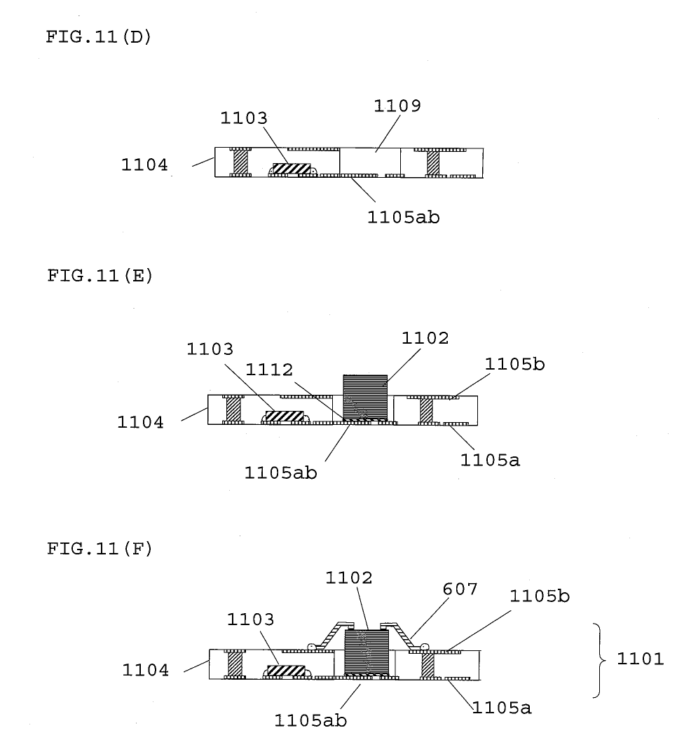

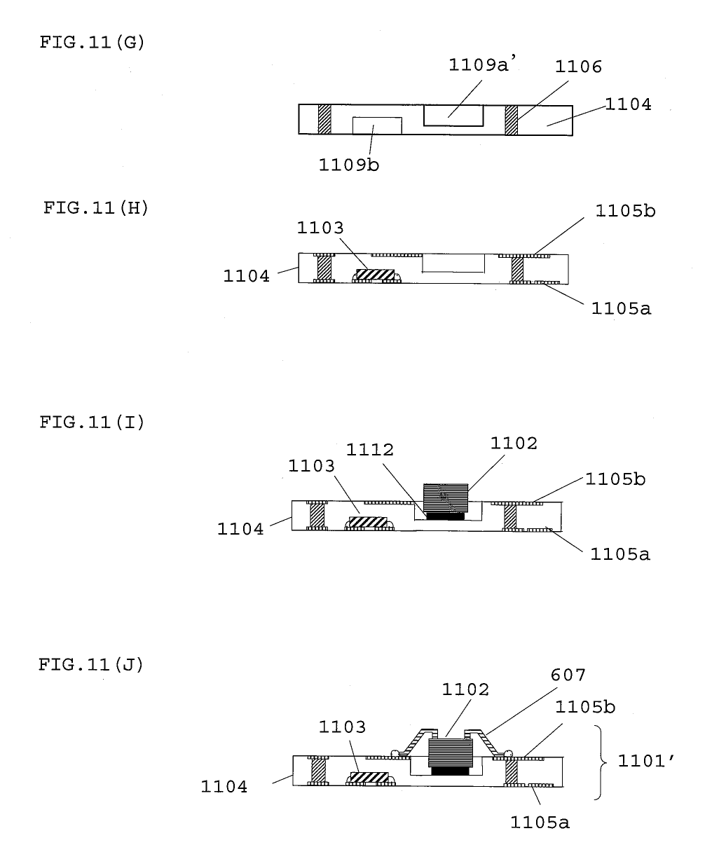

FIGS. 11(A) to 11(E) are sectional views showing a manufacturing method of an electronic component-containing module according to a fourth embodiment of the present invention. The manufacturing method according to the fourth embodiment is an alternative to the manufacturing method of the electronic component-containing module according to the third embodiment and differs from the third embodiment in that a first electronic component 1102 is mounted on a wiring pattern 1105b after a hot-pressing process.

In the fourth embodiment, members corresponding to those of the electronic component-containing module according to the first embodiment are made of the same materials and subjected to the same treatment as the first embodiment.

A manufacturing method for the electronic component-containing module according to the fourth embodiment will be described below with reference to FIGS. 11(A) to 11(E). Detailed description of the same processes as those in the second embodiment will be omitted.

The processes shown in FIGS. 11(A) to 11(E) are practically the same as the processes according to the second embodiment shown in FIGS. 5(A) to 5(E), respectively.

Specifically, in FIG. 11(A), a second electronic component 1103 is mounted on a wiring pattern 1105a formed on a first die release carrier 1107a.

The second electronic component 1103, which is short in height among the electronic components to be incorporated, is connected to the wiring pattern 1105a, for example, by flip-chip mounting (which is a known technique) if the second electronic component 1103 is a bare chip such as an LSI or DRAM, or by soldering if the second electronic component 1103 is a component package such as a BGA or CSP or if the second electronic component 1103 is a chip component such as a resistor or capacitor.

Next, as shown in FIG. 11(B), an inner via 1106 and cavities 1109a and 1109b are formed on an uncured electrically insulating substrate 1104 thinner than the first electronic component 1102 to be mounted later and thicker than the second electronic component 1103. The inner via 1106 is formed to have a diameter of 0.15 mm by laser or punching and filled with a conductive resin paste by printing.

The cavities 1109a and 1109b are formed by laser or punching as in the case of the inner via.

The cavity 1109a has shape and size suitable to accommodate the first electronic component 1102 to be mounted later. Furthermore, the cavity 1109a is formed as a through-hole passing through the electrically insulating substrate 1104 from one surface to the other surface corresponding to the thickness of the first electronic component 1102. On the other hand, the cavity 1109b has shape and size suitable to accommodate the second electronic component 1103. Furthermore, the cavity 1109b is formed as a recess in the electrically insulating substrate 1104 corresponding to the thickness of the second electronic component 1103.

Preferably, the cavity 1109a, in which the first electronic component 1102 is embedded after hot pressing, is processed to be 0.5 mm or more larger than dimensions of the first electronic component 1102, allowing for resin flow of the electrically insulating substrate during the hot pressing.

Next, as shown in FIG. 11(C), the first die release carrier 1107a, electrically insulating substrate 1104, and second die release carrier 1107b are aligned and stacked together, to form a stacked structure, in such a way that the wiring pattern 1105a formed on the first die release carrier 1107a and the wiring pattern 1105b formed on the second die release carrier 1107b will come into contact with the inner via 1106 and that the second electronic component 1103 will fit in the cavity 1109b.

By hot-pressing the stacked structure from outside with the first die release carrier 1107a and second die release carrier 1107b abutted against a pair of press dies 1110a and 1110b, respectively, the second electronic component 1103 is built into the electrically insulating substrate 1104, and the wiring pattern 1105a and wiring pattern 1105b are electrically interconnected via the inner via 1106.

The hot pressing is done at temperatures ranging from 70 to 300° C. and at pressures ranging from 0.1 to 10 MPa, and preferably at temperatures ranging from 150 to 250° C. and at pressures ranging from 0.5 to 5 MPa. During the hot pressing, the uncured electrically insulating substrate 1104 has its viscosity reduced once, and then cures after the second electronic component 1103 to be embedded is buried completely. Consequently, the wiring patterns 1105a and 1105b formed on the first die release carrier 1107a and the second die release carrier 1107b, respectively, are embedded in the electrically insulating substrate 1104 and bonded.

Next, as shown in FIG. 11(D), the first die release carrier 1107a and second die release carrier 1107b are removed. At this time, a wiring pattern 1105ab which is part of the wiring pattern 1105a has been placed on the electrically insulating substrate 1104 so as to close the bottom of the cavity 1109a after the removal.

Next, as shown in FIG. 11(E), the first electronic component 1102 is placed in the cavity 1109a and pasted onto the wiring pattern 1105ab of the wiring pattern 1105a.

The pasting is achieved by means of an adhesive 1112. A method which mounts the first electronic component 1102 with a sheet-type adhesive attached in advance provides high productivity. Suitable materials for the adhesive 1112 include thermosetting epoxy, polyimide, and acrylic resins. It is preferable to use a material which provides high heat resistance.

Finally, as shown in FIG. 11(F), the first electronic component 1102 is connected to a wiring pattern 1105b via wiring 607 to obtain the electronic component-containing module 1101.

The first electronic component 1102 is connected, for example, by wire-bonding if the first electronic component 1102 is an LSI, DRAM or another bare chip or a BGA, CSP, or the like which does not have a lead frame, or by soldering if the first electronic component 1102 has a lead frame.

If a conductive adhesive is used as the adhesive 1112, the first electronic component 1102 can make electrical contacts at two points inside and outside the electrically insulating substrate 1104.

In the above processes, the first die release carrier 1107a is an example of the first die release carrier according to the present invention and the second die release carrier 1107b is an example of the second die release carrier according to the present invention. Also, the electrically insulating substrate 1104 is an example of the electrically insulating substrate according to the present invention. The press dies 1110a and 1110b are examples of the press dies according to the present invention.

Also, the first electronic component 1102 is an example of the particular electronic component according to the present invention and the second electronic component 1103 and wiring pattern 1105a are examples of the plurality of electronic components according to the present invention. Also, the cavity 1109a in the electrically insulating substrate 1104 is an example of the through-hole according to the present invention and the cavity 1109b is an example of the first recess according to the present invention.

Incidentally, to produce a stacked electronic component module shown in FIG. 9 with the first electronic component 902 stacked on the second electronic component 903, the cavity 1109b needed to mount the second electronic component 1103 is omitted from the electrically insulating substrate 1104 in the processes in FIGS. 11(A) to 11(F) and a stack of the first electronic component 902 and second electronic component 903 is mounted in advance instead of the first electronic component 1102 in FIG. 11(E). In that case, the stack of the first electronic component 902 and second electronic component 903 corresponds to the particular electronic component group according to the present invention. In this configuration again, when a second electronic component such as the second electronic component 1103 is used, the cavity 1109b is not omitted.

However, the present invention is not limited to the above processes. Although it has been stated that the electrically insulating substrate 1104 has the cavity 1109 as the through-hole according to the present invention, the electrically insulating substrate 1104 may have a cavity 1109′ as the second recess according to the present invention as shown in FIG. 11(G). The recess 1109′ corresponds to shape and size of the first electronic component 1102 and is large enough to house the first electronic component 1102, but not deep enough to bury the first electronic component 1102 completely.

When the electrically insulating substrate 1104 described above is used, the electronic component-containing module is manufactured by the following method. Specifically, as shown in FIG. 11(H), wiring patterns 1105 are formed by avoiding locations directly below the recess 1109′. Next, as shown in FIG. 11(I), the first electronic component 1102 is pasted to the bottom of the recess 1109′ using the adhesive 1112.

Finally, as shown in FIG. 11(J), the first electronic component 1102 is connected to the wiring pattern 1105b via the wiring 607 and electrical connection of the first electronic component 1102 with other wiring patterns is completed to complete an electronic component-containing module 1101′.

In this configuration example again, it is effective to use the first electronic component 1102 serving as the protruding electronic component according to the present invention with thickness thinner than the electrically insulating substrate 1104. That is, the protruding electronic component according to the present invention needs only to protrude partially from the surface of the substrate in the completed electronic component-containing module, and height of the protruding electronic component as a whole is not limited by the thickness of the substrate.

The fourth embodiment, according to which the first electronic component 1102 is mounted after the hot pressing, can omit forming an opening in the second die release carrier 1107b, and thereby simplify processes, consequently improving productivity.

Since the hot-pressing process does not require a complicated die with a surface depression, it is possible to reduce production costs of the press dies 1110a and 1110b.

### Fifth Embodiment

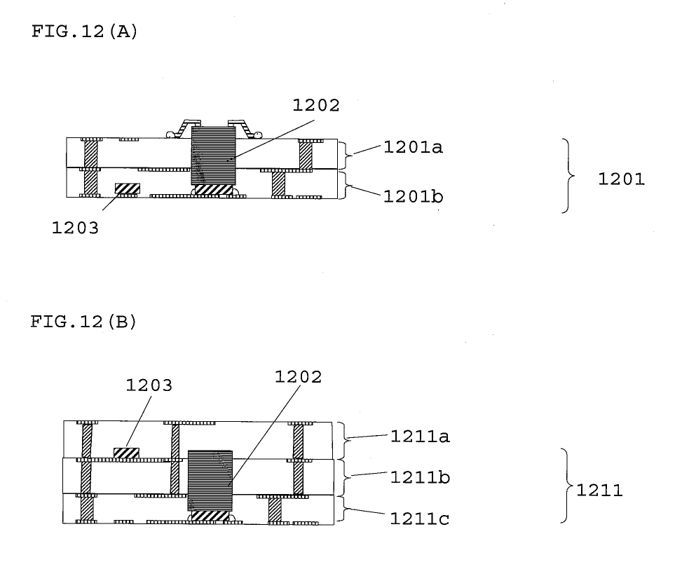

FIG. 12(A) is a sectional view showing a stacked electronic component module according to a fifth embodiment of the present invention. In the fifth embodiment, members corresponding to those of the electronic component-containing module according to the first to fourth embodiments are made of the same materials and subjected to the same treatment as the first to fourth embodiments.

A stacked electronic component module 1201 according to the fifth embodiment has electronic component-containing modules 1201a and 1201b in two layers and a first electronic component 1202 is embedded in such a way as to penetrate the two electronic component-containing modules 1201a and 1201b. The first electronic component 1202 has a part which protrudes from surfaces of both the electronic component-containing modules 1201a and 1201b. A second electronic component 1203 is contained in the electronic component-containing module 1201b.

Thus, the electronic component-containing module 1201b is an example of the electronic component-containing module according to the present invention while the electronic component-containing module 1201a is an example of the conventional electronic component-containing module. Furthermore, the electronic component-containing module 1201a has a through-hole suitable to accommodate the protruding part of the first electronic component 1202 in the electronic component-containing module according to the present invention.

FIG. 12(B) is a block diagram of another example of a stacked electronic component module according to the fifth embodiment. As shown in FIG. 12(B), the stacked electronic component module 1211 has electronic component-containing modules 1211a to 1211c in three layers. The first electronic component 1202 penetrates the electronic component-containing module 1211b and fits in surfaces of the electronic component-containing modules 1211a and 1211c. On the other hand, the second electronic component 1203 is contained in the electronic component-containing module 1211a.

Thus, the electronic component-containing module 1211a is an example of the electronic component-containing module according to the present invention while the electronic component-containing modules 1211b and 1211c are examples of the conventional electronic component-containing module. Furthermore, the electronic component-containing module 1211b has a through-hole suitable to accommodate the protruding part of the first electronic component 1202 in the electronic component-containing module according to the present invention and the electronic component-containing module 1211c has a recess suitable to accommodate the protruding part of the first electronic component 1202 in the electronic component-containing module according to the present invention.

In the stacked electronic component module 1201 or 1211 according to the fifth embodiment with the above configuration, the use of the electronic component-containing module according to the present invention in some layers makes it possible to reduce the overall size of the stacked electronic component module, resulting in richer functionality.

Note that the stacked electronic component module according to the present invention is not limited to the above configuration. In the configuration in which a plurality of electronic component-containing modules are stacked, it is necessary only that at least one layer of electronic component-containing modules includes the electronic component-containing module according to the present invention and that an electronic component-containing module opposite the protruding electronic component of the electronic component-containing module according to the present invention has a recess or through-hole which accommodates the protruding electronic component.

Alternatively, a plurality of the electronic component-containing modules according to the present invention may be stacked consecutively.

The electronic component-containing module 1211b and 1211c to be contained may be produced at least according to any of the first to fourth embodiments or may be produced by another manufacturing method. That is, a stacked electronic component module that includes the configuration of the electronic component-containing module according to the present invention among its inner layers constitutes the stacked electronic component module according to the present invention regardless of specific manufacturing methods or configurations of individual layers.

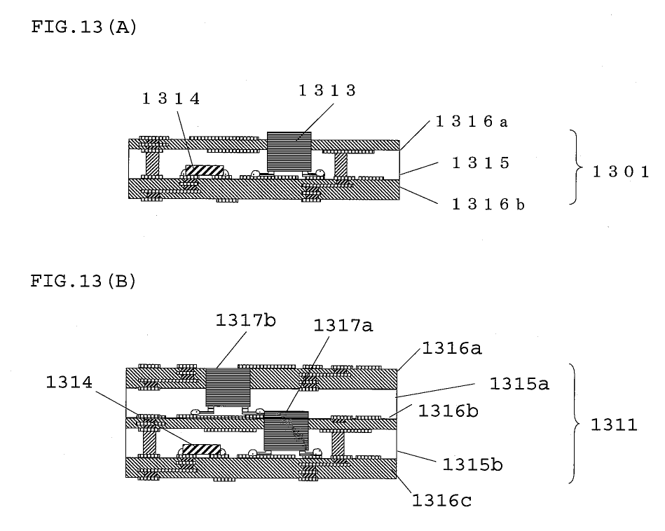

In the above embodiments, surfaces of the electrically insulating substrate are exposed directly from both sides of the electronic component-containing module and the wiring patterns formed on die release carriers are transferred to the electrically insulating substrate. Alternatively, wiring patterns formed on front and rear faces of printed wiring boards 1316a and 1316b may be used as shown in FIG. 13(A). In that case, as its manufacturing method, a stacked structure is built using the printed wiring boards 1316a and 1316b instead of the die release carriers, and the electronic component-containing module is completed without removing the printed wiring boards 1316a and 1316b after hot pressing.

Even in that case, needless to say, an electronic component-containing module 1301, in which a second electronic component 1314 is contained in an electrically insulating substrate 1315 and part of a first electronic component 1313 protrudes from a substrate surface, implements the electronic component-containing module according to the present invention and provides the same advantages as the embodiments described above.

Furthermore, as shown in FIG. 13(B), the invention may be implemented as a stacked electronic component module 1311 with electrically insulating substrates 1315a to 1315b having the printed wiring boards 1316a to 1316c mounted on their surfaces, respectively. In that case again, a configuration in which the second electronic component 1314 is contained in an electrically insulating substrate 1315b directly under the printed wiring board 1316b and part of a first electronic component 1317a protrudes from a substrate surface implements the stacked electronic component module according to the present invention and provides the same advantages as the fifth embodiment.

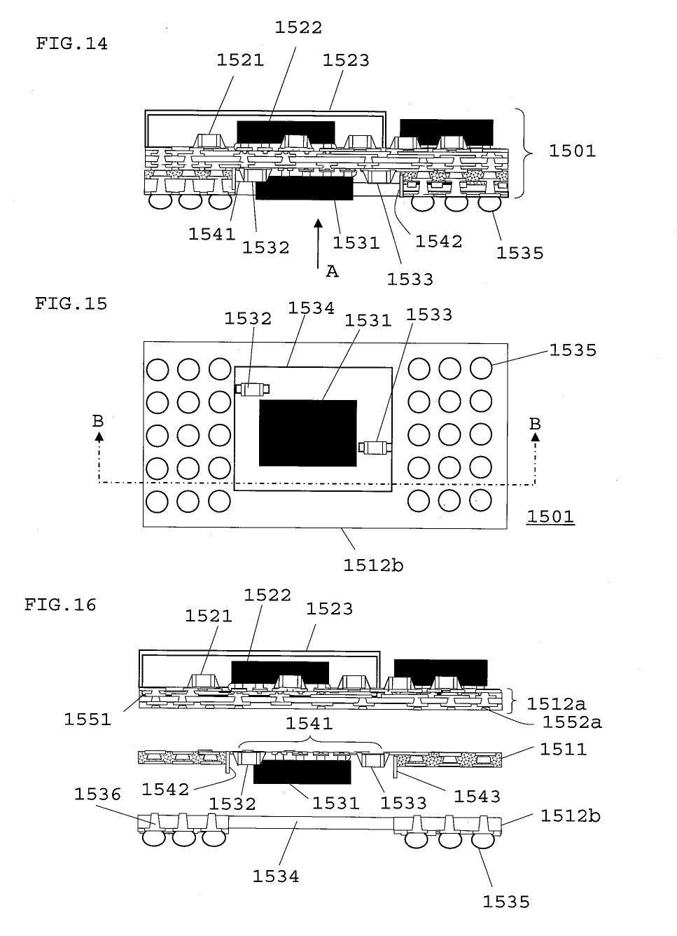

Furthermore, the electronic component-containing module according to the present invention may have a configuration in which printed wiring boards are pasted to both faces of an electrically insulating substrate as shown in FIGS. 14 to 16.

FIG. 14 is a sectional view of an electronic component-containing module 1501. FIG. 15 is a bottom view as viewed from direction A in FIG. 14, which is a sectional view taken along line B-B in FIG. 15. FIG. 16 is an exploded view of the electronic component-containing module 1501 shown in FIG. 14.

As shown in FIGS. 14 to 16, the electronic component-containing module 1501 has an electrically insulating substrate 1511 as well as a printed board 1512a and printed board 1512b which sandwich the electrically insulating substrate 1511 from both sides. The printed board 1512a is a stacked printed board. Electrodes 1551 as well as via holes 1552 and the like for interlayer connection are provided in surfaces and inner layers of the printed board 1512a. Electronic components 1521, 1522, and the like are installed on a surface of the printed board 1512a. A cover 1523 is a member which protects the electronic components 1521, 1522, and the like.

As shown in FIG. 15, there is a rectangular hole 1534 in the printed board 1512b to accommodate a first electronic component 1531 and second electronic components 1532 and 1533 installed on the electrically insulating substrate 1511. Also, solder balls 1535 are provided on a surface of the printed board 1512b as bumps for external connection. The solder balls 1535 are electrically connected to various parts of the electronic component-containing module 1501 through via holes 1536 in the printed board 1512b.

A through-hole 1541 with the same outside dimensions as the hole 1534 is provide in that part of the electrically insulating substrate 1511 which overlaps the hole 1534 in the printed board 1512b to accommodate the first electronic component 1531 and second electronic components 1532 and 1533.

Lateral electrodes 1542 and 1543 are installed on inner side walls of the through-hole 1541 and hole 1534 to also insure external connection. To form the lateral electrodes 1542 and 1543, a copper thin film is formed on the side walls of the hole 1534 and through-hole 1541 by metallizing, the copper thin film is patterned in a desired shape by laser etching, and then a surface of the copper thin film is electroplated with tin or the like. Incidentally, although it has been stated that the lateral electrodes 1542 and 1543 are installed on the inner side walls of the through-hole 1541 and hole 1534, lateral electrodes may be installed on the inner side walls of only one of the through-hole 1541 and hole 1534.

In the above configuration, the printed boards 1512a and 1512b are examples of the printed board according to the present invention. The hole 1534 is an example of the hole according to the present invention. The through-hole 1541 is an example of the through-hole according to the present invention. The solder balls 1535 are an example of the mounting terminals according to the present invention and the lateral electrodes 1542 and 1543 are examples of the electrodes according to the present invention. The first electronic component 1531 is an example of the protruding electronic component according to the present invention. The second electronic components 1532 and 1533 are examples of the plurality of electronic components according to the present invention.

With the above configuration, the electronic component-containing module 1501, in which the second electronic components 1532 and 1533 are contained in the through-hole 1541 in the electrically insulating substrate 1511 and the first electronic component 1531 partially protrudes from the substrate surface as shown in the exploded view in FIG. 16, implements the electronic component-containing module according to the present invention and provides the same advantages as the embodiments described above. Also, outside diameter of the solder balls 1535 is larger than height of the first electronic component 1531 which is exposed from a surface of the printed board 1512b. Consequently, the first electronic component 1531 does not get in the way of mounting the electronic component-containing module 1501 on other equipment. Incidentally, in the configuration shown in FIGS. 14 to 16, the terminals according to the present invention are implemented as the solder balls 1535 which ensure electrical connection between the electronic component-containing module 1501 and external equipment, but the terminals may be implemented simply as spacers made of a resin or other material. Also, in the configurations shown in FIGS. 13 to 16, printed boards (printed wiring boards) are installed on both sides of the electrically insulating substrate, but a printed board may be installed only on one side. Also, any of the printed boards may be made of a single layer or a stack of multiple layers.

In the above description, the term “embed” means the act of setting at least part of an electronic component in an electrically insulating substrate and the term “contain” means the act of enclosing an entire electronic component in the electrically insulating substrate. When a surface of an electronic component is exposed from the electrically insulating substrate, being flush with a surface of the electrically insulating substrate, it is said that the electronic component is “embedded” in the electrically insulating substrate, and the electronic component mounted in this way constitutes an example of the electronic components according to the present invention excluding the protruding electronic component and particular electronic component.

In a configuration example shown in FIGS. 14 to 16, the first electronic component 1531 serving as the protruding electronic component according to the present invention is placed, with clearances, in a space formed by the through-hole 1541 in the electrically insulating substrate 1511 and the hole 1534 in the printed board 1512b. However, the “embedded” state according to the present invention is not limited by the presence or absence of a clearance between the electronic component and electrically insulating substrate. That is, although it has been stated according to the first to fifth embodiments that the electrically insulating substrate according to the present invention is placed in contact with the protruding electronic component or particular electronic component, a clearance may be provided. Also, although it has been stated that two second electronic components 1532 and 1533 are mounted together in the above space, any number of second electronic components may be mounted. Also, only the first electronic component 1531 may be mounted. Also, a recess may be provided in the electrically insulating substrate 1511 instead of the through-hole 1541, and the first electronic component 1531 may be mounted in the recess.

Also, in the configuration examples shown in FIGS. 14 to 16, it has been stated that the first electronic component 1531 serving as the protruding electronic component according to the present invention also protrudes from the surface of the printed board 1512b, but the first electronic component 1531 has only to protrude from the surface of the electrically insulating substrate 1511, being exposed from the surface of the printed board 1512b. That is, the first electronic component 1531 is not restricted by relative position with respect to the surface of the printed board 1512b. Thus, the first electronic component 1531 may be lower than, or flush with, the surface of the printed board 1512b.

The electronic component-containing module and the manufacturing method thereof according to the present invention have the advantage of reducing the thickness of an electrically insulating substrate and thereby reducing the overall size. Thus, the present invention is useful when passive components such as resistors and capacitors or active components such as semiconductor devices are contained in an electrically insulating substrate.

What is claimed is:

1. An electronic component-containing module, comprising:
an electrically insulating substrate; and
a plurality of electronic components embedded in the electrically insulating substrate,
wherein at least one of the plurality of electronic components is a protruding electronic component, part of which protrudes above at least one surface of the electrically insulating substrate, and
the electronic components other than the protruding electronic component are contained so that they do not extend past said at least one surface of the electrically insulating substrate.

2. The electronic component-containing module according to claim 1, further comprising an electrode installed at least on the surface of the electrically insulating substrate, from which the protruding electronic component is exposed, wherein
the protruding electronic component is electrically connected at least to the electrode outside the electrically insulating substrate.

3. The electronic component-containing module according to claim 1, wherein the protruding electronic component is located above the other electronic components.

4. The electronic component-containing module according to claim 1, further comprising a surface-mounted component installed on that surface of the electrically insulating substrate from which the protruding electronic component protrudes.

5. The electronic component-containing module according to claim 1, further comprising a heat dissipating device installed on that part of the protruding electronic component which protrudes from the surface of the electrically insulating substrate.

6. A stacked electronic component module constructed by stacking electronic component-containing modules, comprising:
the electronic component-containing module according to claim 1 as an electronic component-containing module in at least one layer, wherein
a through-hole or a recess is provided in a surface of another electronic component-containing module opposite the electronic component-containing module in at least one layer to accommodate the protruding part of the protruding electronic component.

7. The electronic component-containing module according to claim 1, comprising a printed board bonded to at least one surface of the electrically insulating substrate.

8. The electronic component-containing module according to claim 7, wherein:
the printed board has a hole tailored to shape of the protruding electronic component; and
the protruding electronic component is exposed from the printed board via the hole.

9. The electronic component-containing module according to claim 8, comprising mounting terminals installed on that surface of the printed board which has the hole.

10. The electronic component-containing module according to claim 8, wherein the protruding electronic component is installed in a through-hole or a recess of the electrically insulating substrate, the through-hole or the recess having a shape corresponding to the hole in the printed board.

11. The electronic component-containing module according to claim 10, wherein at least one of the electronic components other than the protruding electronic component is installed in the through-hole or the recess.

12. The electronic component-containing module according to claim 10, comprising one or more electrodes for external electrical connection, the electrode being installed at least either on an inner wall of the hole in the printed board or on an inner wall of the through-hole or the recess in the electrically insulating substrate.

13. A manufacturing method for an electronic component-containing module, comprising:
forming at least a stacked structure of a first die release carrier, a second die release carrier, and an electrically insulating substrate, where a plurality of electronic components including at least one particular electronic component taller than the other electronic components are installed on a surface of the first die release carrier, the second die release carrier has a predetermined through-hole or recess tailored to shape and size of top of the particular electronic component at a location corresponding to a placement location of the particular electronic component, the electrically insulating substrate has a through-hole tailored to shape and size of the particular electronic component and a recess tailored to shape and size of the electronic component other than the particular electronic component, and forming the stacked structure by performing an alignment such that the electrically insulating substrate will be sandwiched between the first die release carrier and the second die release carrier, that the particular electronic component will be passed through the through-hole in the electrically insulating substrate, and that the top of the particular electronic component will be passed through the through-hole in the second die release carrier or fitted in the recess;
pressing and heating the stacked structure from outside both the first die release carrier and the second die release carrier using press dies; and
removing the first die release carrier and the second die release carrier from the stacked structure after the pressing and heating.

14. The manufacturing method for an electronic component-containing module according to claim 13, wherein the particular electronic component protrudes from at least one surface of the electrically insulating substrate.

15. A manufacturing method for an electronic component-containing module, comprising:
forming at least a stacked structure of a first die release carrier, a second die release carrier, and an electrically insulating substrate, where at least one particular electronic component group made up of a plurality of electronic components is stacked on a surface of the first die release carrier, the second die release carrier has a predetermined through-hole or recess tailored to shape and size of top of the particular electronic component group at a location corresponding to a placement location of the particular electronic component group, the electrically insulating substrate has a through-hole tailored to shape and size of the particular electronic component group, and forming the stacked structure by performing an alignment such that the electrically insulating substrate will be sandwiched between the first die release carrier and the second die release carrier, that the particular electronic component group will be passed through the through-hole in the electrically insulating substrate, and that the top of the particular electronic component group will be passed through the through-hole in the second die release carrier or fitted in the recess;
pressing and heating the stacked structure from outside both the first die release carrier and the second die release carrier using press dies; and
removing the first die release carrier and the second die release carrier from the stacked structure after the pressing and heating.

16. The manufacturing method for an electronic component-containing module according to claim 13, wherein:
the second die release carrier has the through-hole tailored to the shape and size of the top of the particular electronic component at the location corresponding to the placement location of the particular electronic component or the particular electronic component group;
the press die which heats and presses the stacked structure from outside the second die release carrier has a recess tailored to the shape of the top of the particular electronic component or the particular electronic component group; and
the press die heats and presses the stacked structure by abutting against the second die release carrier in such a way as to align the recess with the through-hole in the second die release carrier.

17. The manufacturing method for an electronic component-containing module according to claim 15, wherein:
the second die release carrier has the through-hole tailored to the shape and size of the top of the particular electronic component at the location corresponding to the placement location of the particular electronic component or the particular electronic component group;
the press die which heats and presses the stacked structure from outside the second die release carrier has a recess tailored to the shape of the top of the particular electronic component or the particular electronic component group; and
the press die heats and presses the stacked structure by abutting against the second die release carrier in such a way as to align the recess with the through-hole in the second die release carrier.

18. A manufacturing method for an electronic component-containing module, comprising:
forming a stacked structure of a first die release carrier, a second die release carrier, and an electrically insulating substrate, where a plurality of electronic components is installed on the first die release carrier, the electrically insulating substrate has a first recess tailored to shape and size of the plurality of electronic components as well as a through-hole or a second recess tailored to shape and size of at least one particular electronic component, and forming the stacked structure by performing an alignment such that the electrically insulating substrate will be sandwiched between the first die release carrier and the second die release carrier;
pressing and heating the stacked structure from outside both the first die release carrier and the second die release carrier using press dies;
removing the first die release carrier and the second die release carrier from the stacked structure after the pressing and heating; and
mounting the particular electronic component in the through-hole or the second recess of the electrically insulating substrate after the removal of the first die release carrier and the second die release carrier.

19. The manufacturing method for an electronic component-containing module according to claim 18, wherein the particular electronic component protrudes from at least one surface of the electrically insulating substrate.

20. A manufacturing method for an electronic component-containing module, comprising:
forming a stacked structure of a first die release carrier on which a plurality of electronic components are installed, a second die release carrier, and an electrically insulating substrate which has a through-hole or a recess by performing an alignment such that the electrically insulating substrate will be sandwiched between the first die release carrier and the second die release carrier;
pressing and heating the stacked structure from outside both the first die release carrier and the second die release carrier using press dies;
removing the first die release carrier and the second die release carrier from the stacked structure after the pressing and heating; and
mounting a particular electronic component group made up of a plurality of electronic components stacked together in the through-hole or the recess of the electrically insulating substrate after the removal of the first die release carrier and the second die release carrier.

21. The manufacturing method for an electronic component-containing module according to claim 18, wherein:
the through-hole tailored to the shape and size of the particular electronic component or the particular electronic component group is formed in the electrically insulating substrate; and
the through-hole is formed at a location corresponding to part of the plurality of electronic components.

22. The manufacturing method for an electronic component-containing module according to claim 20, wherein:
the through-hole tailored to the shape and size of the particular electronic component or the particular electronic component group is formed in the electrically insulating substrate; and
the through-hole is formed at a location corresponding to part of the plurality of electronic components.
